(19) United States
(12) Patent Application Publication
(10) Pub. No.: US 2025/0077743 A1
(43) Pub. Date: Mar. 6, 2025

(54) A.I. BASED CBR EVENT SOURCE TRACKING SYSTEM AND CONTROLLING METHOD FOR THE SAME

(71) Applicant: AGENCY FOR DEFENSE DEVELOPMENT, Daejeon (KR)

(72) Inventors: Hyunwoo NAM, Daejeon (KR); Jungjae SON, Daejeon (KR); Minjae KANG, Daejeon (KR); Byungheon LEE, Daejeon (KR)

(21) Appl. No.: 18/616,435

(22) Filed: Mar. 26, 2024

(30) Foreign Application Priority Data
Aug. 30, 2023 (KR) 10-2023-0114924

(51) Int. Cl. G06F 30/27

(52) U.S. Cl. CPC G06F 30/27

(57) ABSTRACT

The present invention relates to an A.I. based event source tracking system and a controlling method for the same, and may track a CBR pollution source which is quicker and more reliable by using pollution spread information data for each time zone calculated from a CBR pollution spread prediction modeling tool in a protection region through artificial intelligence technology rather than using real sensor data measured under various environmental conditions in a given zone when a CBR situation occurs, and predict an initial event occurrence source by learning pollution spread (pollution material concentration and deposition amount) information distributed for each time zone on a given space (map) in an image format by using an A.I. based video prediction or next frame prediction).

### CROSS-REFERENCE TO RELATED APPLICATION

This application claims priority to Korean Patent Application No. 10-2023-0114924 filed on Aug. 30, 2024, and all the benefits accruing therefrom under 35 U.S.C. § 119, the contents of which is incorporated by reference in its entirety.

### BACKGROUND OF THE INVENTION

### 1. Field of the Invention

The present invention relates to an A.I. based CBR event source tracking system and a controlling method for the same, and more particularly to learning a time-specific pollution information data acquired by using a pollution spread prediction modeling tool by using a transformer technique which is an artificial intelligence technique in a zone designated by a user, and predicting an accident occurrence source by reversely tracking detection information and time observed or given in the designated zone after an accident occurs based on a learned modeling result.

### 2. Description of the Related Art

In general, various types of gases can be used in industrial sites or storage facilities for various purposes, and in the process of storing and using gases, it is very important to detect and extinguish leaks of lethal or explosive gases at an early stage to prevent human casualties and to prevent the escalation of large-scale accidents. As industrialization has progressed in recent years, various harmful substances are generated not only in industrial complexes where large cities and factories are densely located, but also in rural areas, resulting in increased environmental pollution, which has become a social problem. In addition to such environmental pollution, accidents involving leakage of hazardous substances from factories which handle chemicals harmful to the human body or leakage of harmful gases generated in the process of handling chemicals that are harmful to humans are also frequently occurring, causing human casualties, and moreover, in recent years, the threat of terrorist attacks using chemical weapons has increased due to the rapidly changing international situation. Therefore, in order to prevent unexpected accidents, terrorism, etc. from damaging human lives and property, an early action is very important which monitors the presence and concentration of hazardous substances in the air at all times, detects hazardous gases quickly when the hazardous gases are generated, and evacuates people immediately. In addition, the rapid rise of CBR terrorism in recent years has made it even more dangerous and deadly, so it's imperative to track the CBR terrorism early. In particular, in the CBR terrorism, toxic chemical agents (CWA) used for the purpose of terrorist attacks such as neuropathy and blister agents, and toxic industrial chemicals (TIC) in an industrial complex are colorless and odorless, and in the case of leakage accidents, the leakage accidents can cause massive casualties in a short time. In order to prevent damage to this in advance and monitor the spread of pollution, it is necessary to install and operate sensors in a protected region.

Then, referring to FIG. 1, an example of such a conventional CBR pollution tracking device includes a sensor device 70 for detecting leakage of various hazardous gases, a network interface 71 connected to the sensor device 70 and delivering a detection signal detected by the sensor device 70, a processor 72 connected to the network interface 71 and controlling the entire process of a hazardous gas leak tracking operation, and a memory 73 storing one or more instructions under functional control of the processor 72.

Meanwhile, referring to the operation of the conventional CBR pollution tracking device, first, the processor 72 is connected to the sensor device 70 through the network interface 71 to execute one or more instructions, e.g., a task of tracking whether hazardous gas leaks. In this case, the processor 72 acquires images for a space to be monitored from multiple cameras 74a to 74n provided in the sensor device 70. In addition, the processor 72 checks whether a target object related to the hazardous gas is identified from images photographed by the cameras 74a to 74n of the sensor device 70. Further, when the target object is identified, the processor 72 separates a target object region for the target object from each of the images, and identifies a leakage source at which the target object related to the hazardous gas is generated based on state information for at least one of a shape, a flow, or a motion of the target object shown in the separated target object region. Furthermore, the processor 72 determines whether the hazardous gas leaks based on whether a warning generation condition in which the identified target object is differently set according to at least one of the state information or the leakage source, and stores the determined of whether the hazardous gas leaks in the memory 73 and generates a warning signal. Here, when a processing process of the processor 72 is described in more detail, when it is identified that a leakage amount of the target object identified at the leakage source is more than a first threshold leakage amount, the processor 72 determines that the target object satisfies the warning generation condition, and when it is identified that the leakage amount of the target object identified at the leakage source is equal to or less than the first threshold leakage amount, and is more than a second threshold leakage amount, and a volume of a space to be monitored matched with the leakage source is less than a first threshold volume, the processor 72 determines that the target object satisfies the warning generation condition, and tracks hazardous gas leakage by using the information.

However, the conventional CBR pollution tracking device is limited to installing in a wide range of areas because the sensor devices that can detect pollution in the room including harmful gases are very expensive, and the cost of operating the sensor devices us also very expensive, so the conventional CBR pollution tracking device can only be installed in a limited area within a specific area, and accordingly, many difficulties have been exposed in accurately tracking the source of pollution in the room, and information detected by sensors installed in each area was very difficult to determine how much time has passed since the event occurred and where the initial point of occurrence was, and furthermore, since it relies only on the measurements of the sensor devices installed in a limited area as described above, the process of tracking and predicting a CBR pollution source is not very faithful, and a problem in that there is a very large limit in appropriately responding to dangerous situations is caused.

### SUMMARY OF THE INVENTION

Therefore, the present invention is contrived to solve all problems in the related art, and an object of the present invention is to provide an A.I. based CBR event source tracking system and a controlling method for the same, which can track a CBR pollution source which is more quick and reliable by using pollution spread information data for each time zone calculated from a CBR pollution spread prediction modeling tool in a protection region through artificial intelligence technology rather than using real sensor data measured under various environmental conditions in a given zone when a CBR situation occurs.

Further, another object of the present invention is to provide an A.I. based CBR event source tracking system and a controlling method for the same, which can predict an initial event occurrence source by learning pollution spread (pollution material concentration and deposition amount) information distributed for each time zone on a given space (map) in an image format by using an A.I. based video prediction or next frame prediction).

In order to achieve the objects, the present invention provides an A.I. based CBR event source tracking system including: an input information acquisition unit acquiring model input information for tracking a CBR pollution source; a control module unit controlling a CB pollution source tracking process based on artificial intelligence by using the model input information acquired by the input information acquisition unit, and generating a time inverse calculation-specific pollution spread prediction result generated based on the calculated pollution concentration as output information including an image or a video; a pollution spread prediction modeling data acquisition unit acquiring pollution spread data using a pollution spread prediction modeling tool in the acquired space based on user input information acquired through the input information acquisition unit under functional control of the control module unit; and
a pollution source tracking modeling unit calculating a grid-specific high-resolution pollution concentration in a designation zone (or in a target zone) received as the input information by applying a transformer function which is an artificial intelligence technique based on the model input information acquired through the input information acquisition unit under the functional control of the control module unit.

Further, another feature of the present invention provides the A.I. based CBR event source tracking system in which the model input information of the input information acquisition unit includes at least any one information of modeling target indoor and outdoor space information, CBR pollution source information, and environmental setting information.

Further, another feature of the present invention provides the A.I. based CBR event source tracking system in which the pollution spread prediction modeling data acquisition unit is a pollution spread prediction modeling tool including HPAC and NBC_RAMS.

Further, another feature of the present invention provides the A.I. based CBR event source tracking system in which the pollution spread prediction modeling data acquisition unit further includes a function of acquiring pollution information in the space for each time calculated in order to acquire the pollution spread data by using the pollution spread prediction modeling tool.

Further, another feature of the present invention provides the A.I. based CBR event source tracking system in which the control module unit includes a memory unit storing all data used in a CBR pollution source tracking process based on artificial intelligence, and an output unit displaying output information including an image and graphic data generated in the CBR pollution source tracking process to the outside.

Further, another feature of the present invention provides the A.I. based CBR event source tracking system in which the pollution source tracking modeling unit further includes a function of generating and calculating a pollution source tracking result by inversely calculating a time based on limited pollution concentration data when calculating a grid-specific high-resolution pollution concentration in a designation zone (or a target zone) as the input information by applying the transformer function.

Further, another feature of the present invention provides the A.I. based CBR event source tracking system in which the input information acquisition unit is configured to further include an input inputting space information and environmental setting information to track a pollution source when a CBR event occurs, and a space information acquisition unit acquiring modeling target space information for tracking the pollution source.

Further, another feature of the present invention provides the A.I. based CBR event source tracking system in which the information space acquisition unit further includes a function of configuring a user to select, in a space storing predetermined information for a space to be predicted, the corresponding space.

Further, another feature of the present invention provides the A.I. based CBR event source tracking system in which the information space acquisition unit may acquire outdoor space information defined by the user, and further performs a function including an outdoor amp and topographical information constituted by latitude and longitude information.

Further, another feature of the present invention provides the A.I. based CBR event source tracking system in which the space information acquired by the space information acquisition unit is stored in an internal memory unit through a preprocessing process in order to perform a pollution source tracking modeling function.

Further, another feature of the present invention provides the A.I. based CBR event source tracking system in which the pollution spread prediction modeling data acquisition unit further includes a function of displaying data acquired by predicting the time-wise concentration (mg/m3) as a result calculated through the simulation for the region acquired by the space information acquisition unit by using the pollution spread prediction modeling tool.

Further, another feature of the present invention provides the A.I. based CBR event source tracking system in which the pollution source tracking modeling unit further includes a function of calculating a space in which an event occurrence point is predicted by applying the transformer technology which is the artificial intelligence technique for CBR event information acquired by the user in an input unit, and the zone acquired by the space information acquisition unit and the pollution spread information acquired by the pollution concentration data acquisition unit.

Further, another feature of the present invention provides the A.I. based CBR event source tracking system in which the output unit further includes a function to a pollution source prediction result as an inversely calculated time zone-specific imaging image, and to allow the user to visually track and identify the pollution source under the functional control of the control module unit.

Further, another feature of the present invention provides the A.I. based CBR event source tracking system in which the transformer function of the pollution source tracking modeling unit further includes a function of training sequential spread information of CBR pollutants by using data mapped onto a map, and analyzing a correlation of mapping data for each time zone, and tracking the source in a reverse order of time.

Further, another feature of the present invention provides the A.I. based CBR event source tracking system in which an image data input form of the transformer function has a Rows×Cols×Sequences dimension (a form in which 2D image form of data form layers) in order to perform pollution source tracking.

Further, another feature of the present invention provides the A.I. based CBR event source tracking system in which the transformer function further includes a function of determining a dependency between input frames through a combination of a self attention mechanism, positional encoding, and a decoding layer, and calculating each pixel value (concentration value) of a frame to be predicted, a function of encoding the input image frame (an image frame indicating a pollution concentration value for each grid in a given space) through a self attention layer and a feed forward layer, a function of determining by a decoder of the transformer function, the dependency between the input frames by using the self attention, a function of transforming intermediate representations generated by the decoder into each pixel value of an actual image, and
a function of outputting an image of a next frame (a grid-specific pollution concentration value in a next time zone) in the sequence through the transformed pixel value.

Further, another feature of the present invention provides the A.I. based CBR event source tracking system in which the pollution source tracking modeling unit calculates the grid-specific pollution concentration based on a concentration result inversely calculated for each time zone, which is predicted by using the transformer function and the grid generated in the zone.

Further, another feature of the present invention provides the A.I. based CBR event source tracking system in which the pollution source tracking modeling unit further includes a function of calculating the grid-specific pollution concentration in the designated zone based on the grid by using a GPU parallel high-speed calculation processing technique.

Further, another exemplary embodiment of the present invention provides a controlling method for an A.I. based CBR event source tracking system, including: a first step of acquiring, by an input information acquisition unit, model input information for tracking a CBR pollution source under functional control of a control module unit; a second step of receiving pollution concentration data acquired by using a pollution spread prediction modeling tool by a pollution spread prediction modeling data acquisition unit under the functional control of the control module unit after the second step; a third step of tracking, by a pollution source tracking modeling unit, a pollution source by inversely calculating a grid-specific pollution concentration in the zone by using transformer technology which is an artificial intelligence technique from the acquired space information and pollution spread data under the functional control of the control module unit after the second step; and a fourth step of generating, by the control module unit, a pollution source tracking result generated based on the pollution concentration calculated by the pollution source tracking modeling unit after the third step; and a fifth step of displaying and outputting, by an output unit, under the functional control of the control module unit after the fourth step.

Further, another feature of the present invention provides the controlling method for an A.I. based CBR event source tracking system, in which the first step further includes an input information acquisition step of acquiring, by an input unit of the input information acquisition unit, CBR pollution source information and environmental setting information to be predicted which are input, and a space information acquisition step of acquiring, by a space information acquisition unit of the input information acquisition unit, information on a modeling target outdoor space, in order to acquire model input information.

Further, another feature of the present invention provides the controlling method for an A.I. based CBR event source tracking system, in which the first step further includes a model input information step further including at least any one information of modeling target space information, CBR pollution source information, and environmental setting information in the model input information.

Further, another feature of the present invention provides the controlling method for an A.I. based CBR event source tracking system, in which the first step further includes a step including at least any one of user input information and analysis control setting information in the user input information.

Further, another feature of the present invention provides the controlling method for an A.I. based CBR event source tracking system, in which the first step further includes an information selection step in which pollution source information such as information, type, and physical property of toxic substances of which pollution spread controlled by the control module unit is to be predicted is information stored in a memory, and at least one toxic substance is selected according to an input of the user through an input unit and various information related to the selected toxic substance is selected.

Further, another feature of the present invention provides the controlling method for an A.I. based CBR event source tracking system, in which the second step further includes an offline mode of reading a prestored file and an online mode of loading pollution concentration data while being connected to a network in real time, in a process of receiving time zone-specific pollution concentration data calculated from a CBR pollution prediction tool.

Further, another feature of the present invention provides the controlling method for an A.I. based CBR event source tracking system, in which the third step further includes a step of, in the process of tracking the pollution source by inversely calculating the time from current given pollution spread information currently given by using the pollution source tracking model, calculating a result of tracking the pollution source by using a GPU parallel high-speed calculation processing technique by returning a pollution spread situation several minutes or dozens of minutes before a current time by using a correlation analysis relationship of the time zone-specific pollution spread concentration calculated from the pollution spread prediction modeling tool by using the transformer technology which is the artificial intelligence technique.

Further, another feature of the present invention provides the controlling method for an A.I. based CBR event source tracking system, in which the fourth step further includes a concrete output step of outputting a pollution source prediction result generated based on a time zone-specific pollution concentration calculated by the pollution source tracking modeling unit as output information including a pollution source tracking result image or video under the functional control of the control module unit.

Further, another feature of the present invention provides the controlling method for an A.I. based CBR event source tracking system, in which the concrete output step further includes a sequential display step in which the pollution source tracking result image is sequentially shown according to a user definition or stored and displayed as a moving picture.

Further, another feature of the present invention provides the controlling method for an A.I. based CBR event source tracking system, in which the fourth step further includes step S401 in which the pollution source tracking modeling unit receives, from the model input information acquisition unit, space information including pollution information in a pollution spread target region and a designation zone designated by the user under the functional control of the control module unit, step 402 in which the pollution source tracking modeling unit receives, as input data, time-series pollution concentration image values in the pollution zone sequentially configured based on a modeling result learned by using the transformer technology based on the input information under the functional control of the control module unit, and calculates concentration values in the previous time zone through a pre-learned modeling computation during step 401, step 403 of selecting a zone suspected as a first CBR occurrence region after a predetermined time zone by repeatedly performing step 402 during step 402, and step 404 of reading various setting information acquired by an input information acquisition unit according to an analysis pattern, storing a calculation result in the memory, and storing the calculated result as an image or a moving picture for each time zone according to user setting, and displaying the image or video on a screen through an output unit under the functional control of the control module unit (screen display result) after step 403.

Further, another feature of the present invention provides the controlling method for an A.I. based CBR event source tracking system, in which step 404 further includes a screen display step of displaying, on the screen, pollution concentration prediction values used as in which the screen display result is used as pre-input materials, and pollution concentration result values for each time reverse order predicted by using the transformer technology in an overlay format.

Further, yet another exemplary embodiment of the present invention provides a controlling method for an A.I. based CBR event source tracking system, including: a first step of acquiring, by an input information acquisition unit, model input information including at least any one information of modeling target space information, CBR pollution source information, and environmental setting information under functional control of a control module unit; a second step of receiving pollution concentration data acquired by using a pollution spread prediction modeling tool in a zone under the functional control of the control module unit after the second step; a third step of tracking, by a pollution source tracking modeling unit, a pollution source by inversely calculating a grid-specific pollution concentration in the zone by using transformer technology which is an artificial intelligence technique from the acquired space information and pollution spread data under the functional control of the control module unit after the second step; and a fourth step of generating, by the control module unit, a pollution source tracking result generated based on the pollution concentration calculated by the pollution source tracking modeling unit, and displaying the generated output information to the outside after the third step.

Specific details of other exemplary embodiments are included in “Details for carrying out the invention” and accompanying “drawings”.

Advantages and/or features of the present invention, and a method for achieving the advantages and/or features will become obvious with reference to various exemplary embodiments to be described below in detail together with the accompanying drawings.

However, the present invention is not limited only to a configuration of each exemplary embodiment disclosed below, but may also be implemented in various different forms. The respective exemplary embodiments disclosed in this specification are provided only to complete disclosure of the present invention and to fully provide those skilled in the art to which the present invention pertains with the category of the present invention, and the present invention will be defined only by the scope of each claim of the claims.

According to the present invention, there is an effect in which it is possible to track a CBR pollution source which is quicker and more reliable by using pollution spread information data for each time zone calculated from a CBR pollution spread prediction modeling tool in a protection region through artificial intelligence technology rather than using real sensor data measured under various environmental conditions in a given zone when a CBR situation occurs.

Further, there is also an effect in which it is possible to predict an initial event occurrence source by learning pollution spread (pollution material concentration and deposition amount) information distributed for each time zone on a given space (map) in an image format by using an A.I. based video prediction or next frame prediction).

### BRIEF DESCRIPTION OF THE DRAWINGS

FIG. 1 is a diagram describing an example of a CBR event source tracking apparatus in the relate dart.

FIG. 2 is a diagram describing a configuration of an A.I. based CBR event source tracking system according to an exemplary embodiment of the present invention.

FIG. 3 is a flowchart illustrating a detailed flow of an artificial intelligence based CBR event source tracking method according to an exemplary embodiment of the present invention.

FIG. 4 is a conceptual view describing a concept related to transformer technology related which is artificial intelligence technology used by a pollution source tracking modeling unit in the system of the present invention.

FIG. 5 is a flowchart according to a transformer function applied to the system of the present invention.

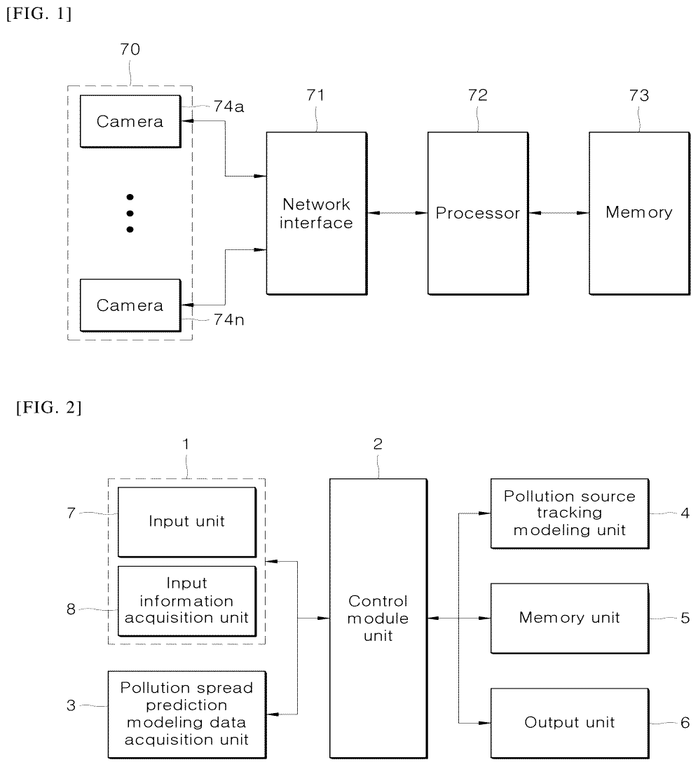

### DETAILED DESCRIPTION OF THE INVENTION

Before describing the present invention in detail, the terms or words used in this specification should not be construed as being unconditionally limited to their ordinary or dictionary meanings, and in order for the inventor of the present invention to describe his/her invention in the best way, concepts of various terms may be appropriately defined and used, and furthermore, the terms or words should be construed as means and concepts which are consistent with a technical idea of the present invention.

That is, the terms used in this specification are only used to describe preferred embodiments of the present invention, and are not used for the purpose of specifically limiting the contents of the present invention, and it should be noted that the terms are defined by considering various possibilities of the present invention.

Further, in this specification, it should be understood that, unless the context clearly indicates otherwise, the expression in the singular may include a plurality of expressions, and similarly, even if it is expressed in plural, it should be understood that the meaning of the singular may be included.

In the case where it is stated throughout this specification that a component “includes” another component, it does not exclude any other component, but further includes any other component unless otherwise indicated.

Furthermore, it should be noted that when it is described that a component “exists in or is connected to” another component, this component may be directly connected or installed in contact with another component, and in inspect to a case where both components are installed spaced apart from each other by a predetermined distance, a third component or means for fixing or connecting the corresponding component to the other component may exist, and the description of the third component or means may be omitted.

On the contrary, when it is described that a component is “directly connected to” or “directly accesses” to another component, it should be understood that the third element or means does not exist.

Similarly, it should be construed that other expressions describing the relationship of the components, that is, expressions such as “between” and “directly between” or “adjacent to” and “directly adjacent to” also have the same purpose.

In addition, it should be noted that if terms such as “one side”, “other side”, “one side”, “other side”, “first”, “second”, etc., are used in this specification, the terms are used to clearly distinguish one component from the other component and a meaning of the corresponding component is not limited used by the terms.

Further, in this specification, if terms related to locations such as “upper”, “lower”, “left”, “right”, etc., are used, it should be understood that the terms indicate a relative location in the drawing with respect to the corresponding component and unless an absolute location is specified for their locations, these location-related terms should not be construed as referring to the absolute location.

Further, in this specification, in specifying the reference numerals for each component of each drawing, the same component has the same reference number even if the component is indicated in different drawings, that is, the same reference number indicates the same component throughout the specification.

In the drawings attached to this specification, a size, a location, a coupling relationship, etc. of each component constituting the present invention may be described while being partially exaggerated, reduced, or omitted for sufficiently clearly delivering the spirit of the present invention, and thus the proportion or scale may not be exact.

Further, hereinafter, in describing the present invention, a detailed description of a configuration determined that may unnecessarily obscure the subject matter of the present invention, for example, a detailed description of a known technology including the prior art may be omitted.

Hereinafter, exemplary embodiments of the present invention will be described in detail with reference to related drawings.

FIG. 2 is a diagram describing a configuration of an A.I. based CBR event source tracking system according to an exemplary embodiment of the present invention.

Referring to FIG. 2, the A.I. based CBR event source tracking system according to the present invention is configured to first include: an input information acquisition unit 1 acquiring model input information for tracking a CBR pollution source; a control module unit 2 controlling a CB pollution source tracking process based on artificial intelligence by using the model input information acquired by the input information acquisition unit 1, and generating a time inverse calculation-specific pollution spread prediction result generated based on the calculated pollution concentration as output information including an image or a video; a pollution spread prediction modeling data acquisition unit 3 acquiring pollution spread data using a pollution spread prediction modeling tool in the acquired space based on user input information acquired through the input information acquisition unit 1 under functional control of the control module unit 2; and a pollution source tracking modeling unit 4 calculating a grid-specific high-resolution pollution concentration in a designation zone (or in a target zone) received as the input information by applying a transformer function which is an artificial intelligence technique based on the model input information acquired through the input information acquisition unit 1 under the functional control of the control module unit 2.

In addition, the model input information of the input information acquisition unit 1 includes at least any one information of modeling target indoor and outdoor space information, CBR pollution source information, and environmental setting information.

Further, a pollution spread prediction modeling tool of the pollution spread prediction modeling data acquisition unit 3 includes HPAC and NBC_RAMS.

In addition, the pollution spread prediction modeling data acquisition unit 3 further includes a function of acquiring pollution information in the space for each time calculated in order to acquire the pollution spread data by using the pollution spread prediction modeling tool.

Furthermore, the control module unit 2 includes a memory unit 5 storing all data used in a CBR pollution source tracking process based on artificial intelligence, and an output unit 6 displaying output information including an image and graphic data generated in the CBR pollution source tracking process to the outside.

Further, the pollution source tracking modeling unit 4 further includes a function of generating and calculating a pollution source tracking result by inversely calculating a time based on limited pollution concentration data when calculating a grid-specific high-resolution pollution concentration in a designation zone (or a target zone) as the input information by applying the transformer function.

Here, the input information acquisition unit 1 is configured to further include an input unit 7 inputting space information and environmental setting information to track a pollution source when a CBR event occurs, and a space information acquisition unit 8 acquiring modeling target space information for tracking the pollution source.

In this case, as a limited example, the input unit 7 further includes a function of inputting environmental setting information including various conditions and settings for modeling. In addition, the information space acquisition unit 8 further includes a function of configuring a user to select, in a space storing predetermined information for a space to be predicted, the corresponding space.

Further, the information space acquisition unit 8 may acquire outdoor space information defined by the user, and further perform a function including an outdoor amp and topographical information constituted by latitude and longitude information. Furthermore, the space information acquired by the space information acquisition unit 8 is stored in an internal memory unit 5 through a preprocessing process in order to perform a pollution source tracking modeling function.

Further, the pollution spread prediction modeling data acquisition unit 3 further includes a function of displaying data acquired by predicting the time-wise concentration (mg/m3) as a result calculated through the simulation for the region acquired by the space information acquisition unit 8 by using the pollution spread prediction modeling tool.

Further, the pollution source tracking modeling unit 4 further includes a function of calculating a space in which an event occurrence point is predicted by applying the transformer technology which is the artificial intelligence technique for CBR event information acquired by the user in the input unit 7, and the zone acquired by the space information acquisition unit 8 and the pollution spread information acquired by the pollution concentration data acquisition unit.

Meanwhile, the memory unit 5 may store various data and programs for the motion of the A.I. based event source tracking system 9 according to an exemplary embodiment of the present invention.

Further, the memory unit 5 may store spatial information, a CBR pollutant library, and various environmental setting information for tracking the CBR pollution source.

In addition, the input unit 7 as a component for receiving pollutant information, time zone-specific pollution spread prediction modeling data, external environment information (weather information), and analysis setting and predefinition information to predict the pollution source from the user may include a mechanical input means and a touch type input means.

Meanwhile, pollution source information such as information, a type, and a physical property of a toxic substance to predict the pollution spread controlled by the control module unit 2 may be information stored in the memory unit 5. In this case, at least one toxic substance may be selected according to an input of the user through the input unit 7 and various information related to the selected toxic substance may be selected.

In addition, the output unit 6 may output various data of the artificial intelligence based CBR threat prediction system 9 according to an exemplary embodiment of the present invention according to the functional control of the control module unit 2. For example, the output unit 6 further includes a function to a pollution source prediction result as an inversely calculated time zone-specific imaging image, and to allow the user to visually track and identify the pollution source under the functional control of the control module unit.

To this end, the output unit 6 may include at least one display capable of displaying image information. Here, the display may be implemented as a Cathode Ray Tube (CRT), a Plasma Display Panel (PDP), a Liquid Crystal Display (LCD), a Light Emitting Diode (LED), an Organic Light Emitting Diode (OLED), etc., but is not limited thereto.

Meanwhile, the control module unit 2 may control an overall motion of the A.I. based CBR event source tracking system 9 according to an exemplary embodiment of the present invention. For example, the control module unit 2 may control a motion and a motion order of each connected component, and control each connected component based on the information input through the input unit 7. Further, the control module unit 2 may be selected with and receive at least one in a CBRN pollutant list prestored for tracking a CBR pollution source through the input unit 121.

Meanwhile, the transformer technology of the pollution source tracking modeling unit 4 is a neural network that learns a context and a meaning by primarily tracking a relationship in sequential texts, or images, and video data.

More specifically, a transformer function of the pollution source tracking modeling unit 4 is a technique that analyzes a meaning relationship of data elements separated from each other by applying a mathematical technique which repeatedly evolves while being called attention or self-attention. The transformer function applied to the pollution source tracking modeling unit 4 according to an exemplary embodiment of the present invention performs a function of training sequential spread information of CBR pollutants by using data mapped onto a map, and analyzing a correlation of mapping data for each time zone, and tracking the source in a reverse order of time.

Such a transformer function shows a more rapid learning processing ability in a parallel processing mode by comparing with an existing convolutional LSTM mode, and is more advantageous in learning a relationship of sequential data which is far from each other in a temporal order, and to be more useful as detailed technology for a purpose of tracking the CBR pollution source.

In this case, an image data input form of the transformer which performs pollution source tracking has a dimension of Rows×Cols×Sequences. That is, the image data input form is a form in which a 2D image form of data forms layers, and a part corresponding to one layer in the entire input data means a 2D distribution of concentrations of CBR pollutants according to a space.

Additionally, the transformer function requires another input data to receive images of multiple frames in parallel when receiving sequential data which are not permitted to be mixed, and this is called positional encoding. Another data is added to embedded vectors, which includes temporal order information of the vectors, so even though images corresponding to each frame are input into a model at once, the model may consider order information of the input images. In this case, the positional encoding vector also has the dimension of Rows×Cols×Sequences like an input image sequence.

Further, the transformer function determines a dependency between input frames through a combination of a self attention mechanism, positional encoding, and a decoding layer, and calculates each pixel value (concentration value) of a frame to be predicted. In addition, the input image frame (an image frame indicating a pollution concentration value for each grid in a given space) is encoded through a self attention layer and a feed forward layer. Further, a decoder of the transformer function determines the dependency between the input frames by using the self attention. Thereafter, intermediate representations generated by the decoder are converted into each pixel value of an actual image. Here, the process is called transforming a decoder output into a pixel space. Through this, the transformer function outputs an image of a next frame (a grid-specific pollution concentration value in a next time zone) in the sequence.

Accordingly, the pollution source tracking modeling unit 4 may calculate the grid-specific pollution concentration based on a concentration result inversely calculated for each time zone, which is predicted by using the transformer function and the grid generated in the zone.

Furthermore, the pollution source tracking modeling unit 4 further includes a function of calculating the grid-specific pollution concentration in the designated zone based on the grid by using a GPU parallel high-speed calculation processing technique.

Meanwhile, the A.I. based CBR event source tracking system according to an exemplary embodiment of the present invention is possible to implement as a computer readable code in a medium having a program recorded therein. In addition, the computer readable medium includes all kinds of recording devices storing data which may be deciphered by a computer system. Examples of the computer readable recording medium include a Hard Disk Drive (HDD), a Solid State Disk (SSD), a Silicon Disk Drive (SDD), a ROM, a RAM, a CD-ROM, a magnetic tape, a floppy disk, an optical data storage device, and the like and further include a device implemented as a type of a carrier wave (e.g., transmission through the Internet). Further, the computer may also include the control module unit 2.

As an example, as a Chemical, Biological, and Radiological (CBR) pollution-proliferation prediction tool), there a Nuclear, Biological, and Chemical Reporting And Modeling S/W System (hereinafter, NBC_RAMS) developed by the Defense Research Institute, and there is a HAZARD prediction and assessment capability (HPAC) system which is a hazard substance proliferation and influence prediction model in the atmosphere developed by the US Defense Threat Reduction Agency (DTRA).

That is, when the A.I. based CBR event source tracking system according to an exemplary embodiment of the present invention is summarized in brief, a system is provided, which learns pollution prediction information for each time zone with various outdoor spaces defined by a user as a background to track a pollution source based on modeling materials learned from information measured when a CBR event occurs in the designated zone.

Next, a controlling method of an exemplary embodiment of the present invention configured as above will be described.

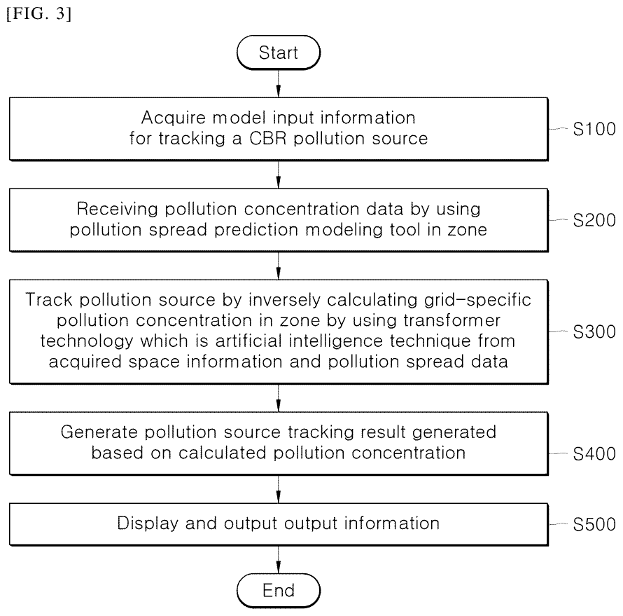

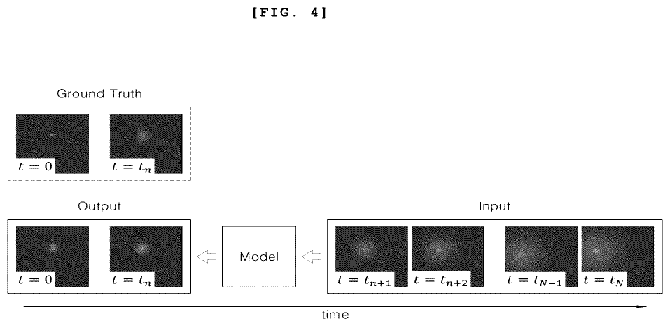

FIG. 3 is a flowchart illustrating a detailed flow of an artificial intelligence based CBR event source tracking method according to an exemplary embodiment of the present invention.

Referring to FIG. 3, the method of the present invention includes: a first step S100 of acquiring, by an input information acquisition unit, model input information for tracking a CBR pollution source under functional control of a control module unit; a second step S200 of receiving pollution concentration data acquired by using a pollution spread prediction modeling tool by a pollution spread prediction modeling data acquisition unit under the functional control of the control module unit after the second step S100; a third step S300 of tracking, by a pollution source tracking modeling unit, a pollution source by inversely calculating a grid-specific pollution concentration in the zone by using transformer technology which is an artificial intelligence technique from the acquired space information and pollution spread data under the functional control of the control module unit after the second step S200; and a fourth step S400 of generating, by the control module unit, a pollution source tracking result generated based on the pollution concentration calculated by the pollution source tracking modeling unit after the third step S300; and a fifth step S500 of displaying and outputting, by an output unit, under the functional control of the control module unit after the fourth step S400.

Here, the first step S100 may be configured to further include an input information acquisition step of acquiring, by an input unit of the input information acquisition unit, CBR pollution source information and environmental setting information to be predicted which are input, and a space information acquisition step of acquiring, by a space information acquisition unit of the input information acquisition unit, information on a modeling target outdoor space, in order to acquire model input information.

Further, the first step S100 further includes a model input information step further including at least any one information of modeling target space information, CBR pollution source information, and environmental setting information in the model input information.

In addition, the first step S100 further includes a step including at least any one of user input information and analysis control setting information in the user input information.

Further, the second step S200 further includes an offline mode of reading a prestored file and an online mode of loading pollution concentration data while being connected to a network in real time, as a step of receiving time zone-specific pollution concentration data calculated from a CBR pollution prediction tool.

Further, the third step S300 may be configured to further include a step of, as a step of tracking the pollution source by inversely calculating the time from current given pollution spread information currently given by using the pollution source tracking model, calculating a result of tracking the pollution source by using a GPU parallel high-speed calculation processing technique by returning a pollution spread situation several minutes or dozens of minutes before a current time by using a correlation analysis relationship of the time zone-specific pollution spread concentration calculated from the pollution spread prediction modeling tool by using the transformer technology which is the artificial intelligence technique.

In addition, the fourth step S400 may be configured to further include a concrete output step of outputting a pollution source prediction result generated based on a time zone-specific pollution concentration calculated by the pollution source tracking modeling unit as output information including a pollution source tracking result image or video under the functional control of the control module unit.

Here, the concrete output step may further include a sequential display step in which the pollution source tracking result image is sequentially shown according to a user definition or stored and displayed as a moving picture.

Meanwhile, FIG. 4 is a conceptual view describing a concept related to transformer technology related which is artificial intelligence technology used by a pollution source tracking modeling unit in the system of the present invention.

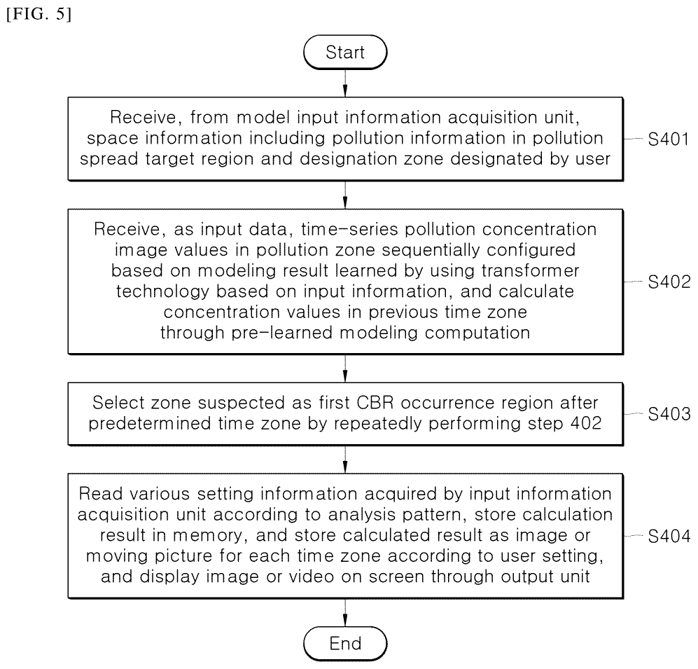

FIG. 5 is a flowchart according to a transformer function applied to the system of the present invention.

Referring to FIGS. 4 and 5 above, the fourth step S400 may be configured to further include step S401 in which the pollution source tracking modeling unit receives, from the model input information acquisition unit, space information including pollution information in a pollution spread target region and a designation zone designated by the user under the functional control of the control module unit, step 402 S402 in which the pollution source tracking modeling unit receives, as input data, time-series pollution concentration image values in the pollution zone sequentially configured based on a modeling result learned by using the transformer technology based on the input information under the functional control of the control module unit, and calculates concentration values in the previous time zone through a pre-learned modeling computation during step 401 S401, step 403 S403 of selecting a zone suspected as a first CBR occurrence region after a predetermined time zone by repeatedly performing step 402 S402 during step 402 S402, and step 404 S404 of reading various setting information acquired by an input information acquisition unit according to an analysis pattern, storing a calculation result in the memory, and storing the calculated result as an image or a moving picture for each time zone according to user setting, and displaying the image or video on a screen through an output unit under the functional control of the control module unit after step 403 S403.

Here, step 404 S404 further includes a screen display step of displaying, on the screen, pollution concentration prediction values used as in which the display result is used as pre-input materials, and pollution concentration result values for each time reverse order predicted by using the transformer technology in an overlay format.

In other words, in the A.I. based CBR event source tracking system according to the exemplary embodiment of the present invention, the input information acquisition unit 1 first acquires model input information for tracking a CBR pollution source under a functional control of the control module 2. In this process, the input information acquisition unit 1 acquires CBR pollution source information and environmental setting information to be predicted, which is input through the input unit 7, and at the same time, acquires a modeling target outdoor space through the space information acquisition unit 8. In addition, the input information acquisition unit 1 further includes at least any one information of the modeling target space information, the CBR pollution source information, and the environmental setting information in the model input information. Further, the input information acquisition unit 1 further includes at least any one of user input information and analysis control setting information in the model input information in the input information process.

In addition, after the process of acquiring the model input information as described above, the pollution spread prediction modeling data acquisition unit 3 receives pollution concentration data by using a pollution spread prediction modeling tool in a zone under the functional control of the control module unit 2. That is, the pollution spread prediction modeling data acquisition unit 3 executes an offline mode of reading a prestored file and an online mode of loading pollution concentration data while being connected to a network in real time, as a step of receiving time zone-specific pollution concentration data calculated from a CBR pollution prediction tool.

Further, when the pollution spread prediction modeling data is acquired as described above, the pollution source tracking modeling unit 4 tracks a pollution source by calculating the grid-specific pollution concentration in the zone from the acquired space information and pollution spread data in a time inverse calculation by using transformer technology which is an artificial intelligence technique under the functional control of the control module unit 2. That is, the pollution source tracking modeling unit 4 tracks the pollution source by inversely calculating the time from current given pollution spread information currently given by using the pollution source tracking model, and in this case, calculates a result of tracking the pollution source by returning a pollution spread situation several minutes or dozens of minutes before a current time by using a correlation analysis relationship of the time zone-specific pollution spread concentration calculated from the pollution spread prediction modeling tool by using the transformer technology which is the artificial intelligence technique, and calculates the calculated result by using a GPU parallel high-speed calculation processing technique.

Here, the transformer function executed by the pollution source tracking modeling unit 4 is a neural network that learns a context and a meaning by primarily tracking a relationship in sequential texts, or images, and video data. Accordingly, the transformer function of the pollution source tracking modeling unit 4 is a technique that analyzes a meaning relationship of data elements separated from each other by applying a mathematical technique which repeatedly evolves while being called attention or self-attention. Furthermore, the transformer function applied to the pollution source tracking modeling unit 4 performs a function of training sequential spread information of CBR pollutants by using data mapped onto a map, and analyzing a correlation of mapping data for each time zone, and tracking the source in a reverse order of time. Such a transformer function shows a more rapid learning processing ability in a parallel processing mode by comparing with an existing convolutional LSTM mode, and is more advantageous in learning a relationship of sequential data which is far from each other in a temporal order, and to be more useful as detailed technology for a purpose of tracking the CBR event source.

In this case, an image data input form of the transformer which performs pollution source tracking has a dimension of Rows×Cols×Sequences. That is, the image data input form is a form in which a 2D image form of data forms layers, and a part corresponding to one layer in the entire input data means a 2D distribution of concentrations of CBR pollutants according to a space.

Additionally, the transformer function requires another input data to receive images of multiple frames in parallel when receiving sequential data which are not permitted to be mixed, and this is called positional encoding. Another data is added to embedded vectors, which includes temporal order information of the vectors, so even though images corresponding to each frame are input into a model at once, the model may consider order information of the input images. In this case, the positional encoding vector also has the dimension of Rows×Cols×Sequences like the input image sequence.

Further, the transformer function determines a dependency between input frames through a combination of a self attention mechanism, positional encoding, and a decoding layer, and calculates each pixel value (concentration value) of a frame to be predicted. In addition, the input image frame (an image frame indicating a pollution concentration value for each grid in a given space) is encoded through a self attention layer and a feed forward layer. Further, a decoder of the transformer function determines the dependency between the input frames by using the self attention. Thereafter, intermediate representations generated by the decoder are converted into each pixel value of an actual image. Here, the process is called transforming a decoder output into a pixel space. Through this, the transformer function outputs an image of a next frame (a grid-specific pollution concentration value in a next time zone) in the sequence.

Accordingly, the pollution source tracking modeling unit 4 may calculate the grid-specific pollution concentration based on a concentration result inversely calculated for each time zone, which is predicted by using the transformer function and the grid generated in the zone.

Furthermore, the pollution source tracking modeling unit 4 further includes a function of calculating the grid-specific pollution concentration in the designated zone based on the grid by using a GPU parallel high-speed calculation processing technique.

In addition, when the CBR pollution source is tracked through such a process, the control module unit 2 generates the pollution source tracking result generated based on the pollution concentration calculated by the pollution source tracking modeling unit 4 as output information including an image or video, and displays and outputs the output information through the output unit 6.

That is, the pollution source tracking modeling unit 4 may generate the pollution source prediction result generated on the calculated time zone-specific pollution concentration as output information including a pollution source tracking result image or video under the functional control of the control module unit, and the pollution source tracking result image may also be sequentially shown according to a user definition, or stored and displayed as a moving picture.

Meanwhile, a pollution source tracking process implemented by the pollution source tracking modeling unit is described below in more detail with reference to FIG. 4.

That is, the pollution source tracking modeling unit 4 receives, from the model input information acquisition unit 1, space information including pollution information in a pollution spread target region and a designation zone designated by the user under the functional control of the control module unit 2. In addition, when receiving the model input information as described above, the pollution source tracking modeling unit 4 receives, as input data, time-series pollution concentration image values in the pollution zone sequentially configured based on a modeling result learned by using the transformer technology based on the input information under the functional control of the control module unit 2, and calculates concentration values in the previous time zone through a pre-learned modeling computation. In this case, the pollution source tracking modeling unit 4 repeatedly performs a process of calculating the concentration values in the previous time zone through the pre-learned transformer modeling computation to select a zone suspected as a region where pollution occurs after a predetermined zone, e.g., a region estimated as the CBR pollution source.

In addition, the pollution source tracking modeling unit 4 reads various setting information acquired by an input information acquisition unit 1 according to an analysis pattern, stores a calculation result in the memory unit 6, and stores the calculated result as an image or a moving picture for each time zone according to user setting, and displays the image or video on a screen through an output unit 6 under the functional control of the control module unit 2.

In this case, the pollution source tracking modeling unit 4 may display, on the screen, pollution concentration prediction values used as in which the display result is used as pre-input materials, and pollution concentration result values for each time reverse order predicted by using the transformer technology in an overlay format, under the functional control of the control module unit 2.

As described above, according to the present invention, there is an effect in which it is possible to track a CBR event source which is quicker and more reliable by using pollution spread information data for each time zone calculated from a CBR pollution spread prediction modeling tool in a protection region through artificial intelligence technology rather than using real sensor data measured under various environmental conditions in a given zone when a CBR situation occurs.

Further, it is possible to predict an initial event occurrence source by learning pollution spread (pollutant concentration and deposition amount) information distributed for each time zone on a given space (map) in an image format by using an A.I. based video prediction or next frame prediction).

In the above, although several preferred embodiments of the present invention have been described with some examples, the descriptions of various exemplary embodiments described in the “Specific Content for Carrying Out the Invention” item are merely exemplary, and it will be appreciated by those skilled in the art that the present invention can be variously modified and carried out or equivalent executions to the present invention can be performed from the above description.

In addition, since the present invention can be implemented in various other forms, the present invention is not limited by the above description, and the above description is for the purpose of completing the disclosure of the present invention, and the above description is just provided to completely inform those skilled in the art of the scope of the present invention, and it should be known that the present invention is only defined by each of the claims.

What is claimed is:

1. An A.I. based CBR event source tracking system comprising:
an input information acquisition unit acquiring model input information for tracking a CBR pollution source;
a control module unit controlling a CB pollution source tracking process based on artificial intelligence by using the model input information acquired by the input information acquisition unit, and generating a time inverse calculation-specific pollution spread prediction result generated based on the calculated pollution concentration as output information including an image or a video;
a pollution spread prediction modeling data acquisition unit acquiring pollution spread data using a pollution spread prediction modeling tool in the acquired space based on user input information acquired through the input information acquisition unit under functional control of the control module unit; and
a pollution source tracking modeling unit calculating a grid-specific high-resolution pollution concentration in a designation zone (or in a target zone) received as the input information by applying a transformer function which is an artificial intelligence technique based on the model input information acquired through the input information acquisition unit under the functional control of the control module unit.

2. The A.I. based CBR event source tracking system of claim 1, wherein the model input information of the input information acquisition unit includes at least any one information of modeling target indoor and outdoor space information, CBR pollution source information, and environmental setting information.

3. The A.I. based CBR event source tracking system of claim 1, wherein the pollution spread prediction modeling data acquisition unit is a pollution spread prediction modeling tool including HPAC and NBC_RAMS.

4. The A.I. based CBR event source tracking system of claim 1, wherein the pollution spread prediction modeling data acquisition unit further includes a function of acquiring pollution information in the space for each time calculated in order to acquire the pollution spread data online/offline by using the pollution spread prediction modeling tool.

5. The A.I. based CBR event source tracking system of claim 1, wherein the control module unit includes a memory unit storing all data used in a CBR pollution source tracking process based on artificial intelligence, and an output unit displaying output information including an image and graphic data generated in the CBR pollution source tracking process to the outside.

6. The A.I. based CBR event source tracking system of claim 1, wherein the pollution source tracking modeling unit further includes a function of generating and calculating a pollution source tracking result by inversely calculating a time based on limited pollution concentration data when calculating a grid-specific high-resolution pollution concentration in a designation zone (or a target zone) as the input information by applying the transformer function.

7. The A.I. based CBR event source tracking system of claim 1, wherein the input information acquisition unit is configured to further include an input unit inputting space information and environmental setting information to track a pollution source when a CBR event occurs, and a space information acquisition unit acquiring modeling target space information for tracking the pollution source.

8. The A.I. based CBR event source tracking system of claim 7, wherein the information space acquisition unit further includes a function of configuring a user to select, in a space storing predetermined information for a space to be predicted, the corresponding space.

9. The A.I. based CBR event source tracking system of claim 7, wherein the information space acquisition unit may acquire outdoor space information defined by the user, and further performs a function including an outdoor amp and topographical information constituted by latitude and longitude information.

10. The A.I. based CBR event source tracking system of claim 7, wherein the space information acquired by the space information acquisition unit is stored in an internal memory unit through a preprocessing process in order to perform a pollution source tracking modeling function.

11. The A.I. based CBR event source tracking system of claim 1, wherein the pollution spread prediction modeling data acquisition unit further includes a function of displaying data acquired by predicting the time-wise concentration (mg/m3) as a result calculated through the simulation for the region acquired by a space information acquisition unit by using the pollution spread prediction modeling tool.

12. The A.I. based CBR event source tracking system of claim 1, wherein the pollution source tracking modeling unit further includes a function of calculating a space in which an event occurrence point is predicted by applying the transformer technology which is the artificial intelligence technique for CBR event information acquired by the user in an input unit, and the zone acquired by a space information acquisition unit and the pollution spread information acquired by the pollution concentration data acquisition unit.

13. The A.I. based CBR event source tracking system of claim 5, wherein the output unit further includes a function to a pollution source prediction result as an inversely calculated time zone-specific imaging image, and to allow the user to visually track and identify the pollution source under the functional control of the control module unit.

14. The A.I. based CBR event source tracking system of claim 1, wherein the transformer function of the pollution source tracking modeling unit further includes a function of training sequential spread information of CBR pollutants by using data mapped onto a map, and analyzing a correlation of mapping data for each time zone, and tracking the source in a reverse order of time.

15. The A.I. based CBR event source tracking system of claim 14, wherein an image data input form of the transformer function has a Rows×Cols×Sequences dimension (a form in which 2D image form of data form layers) in order to perform pollution source tracking.

16. The A.I. based CBR event source tracking system of claim 14, wherein the transformer function further includes a function of determining a dependency between input frames through a combination of a self attention mechanism, positional encoding, and a decoding layer, and calculating each pixel value (concentration value) of a frame to be predicted,
a function of encoding the input image frame (an image frame indicating a pollution concentration value for each grid in a given space) through a self attention layer and a feed forward layer,
a function of determining by a decoder of the transformer function, the dependency between the input frames by using the self attention,
a function of transforming intermediate representations generated by the decoder into each pixel value of an actual image, and
a function of outputting an image of a next frame (a grid-specific pollution concentration value in a next time zone) in the sequence through the transformed pixel value.

17. The A.I. based CBR event source tracking system of claim 1, wherein the pollution source tracking modeling unit calculates the grid-specific pollution concentration based on a concentration result inversely calculated for each time zone, which is predicted by using the transformer function and the grid generated in the zone.

18. The A.I. based CBR event source tracking system of claim 1, wherein the pollution source tracking modeling unit further includes a function of calculating the grid-specific pollution concentration in the designated zone based on the grid by using a GPU parallel high-speed calculation processing technique.

19. A controlling method for an A.I. based CBR event source tracking system, comprising:
a first step of acquiring, by an input information acquisition unit, model input information for tracking a CBR pollution source under functional control of a control module unit;
a second step of receiving pollution concentration data acquired by using a pollution spread prediction modeling tool in a zone by a pollution spread prediction modeling data acquisition unit under the functional control of the control module unit after the first step;
a third step of tracking, by a pollution source tracking modeling unit, a pollution source by inversely calculating a grid-specific pollution concentration in the zone by using transformer technology which is an artificial intelligence technique from the acquired space information and pollution spread data under the functional control of the control module unit after the second step;
a fourth step of generating, by the control module unit, a pollution source tracking result generated based on the pollution concentration calculated by the pollution source tracking modeling unit after the third step; and
a fifth step of displaying and outputting, by an output unit, the output information under the functional control of the control module unit after the fourth step.

20. The controlling method for an A.I. based CBR event source tracking system of claim 19, wherein the first step further includes an input information acquisition step of acquiring, by an input unit of the input information acquisition unit, CBR pollution source information and environmental setting information to be predicted which are input, and a space information acquisition step of acquiring, by a space information acquisition unit of the input information acquisition unit, information on a modeling target outdoor space, in order to acquire model input information.

21. The controlling method for an A.I. based CBR event source tracking system of claim 19, wherein the first step further includes a model input information step further including at least any one information of modeling target space information, CBR pollution source information, and environmental setting information in the model input information.

22. The controlling method for an A.I. based CBR event source tracking system of claim 19, wherein the first step further includes a step including at least any one of user input information and analysis control setting information in the user input information.

23. The controlling method for an A.I. based CBR event source tracking system of claim 19, wherein the first step further includes an information selection step in which pollution source information such as information, type, and physical property of toxic substances of which pollution spread controlled by the control module unit is to be predicted is information stored in a memory, and at least one toxic substance is selected according to an input of the user through an input unit and various information related to the selected toxic substance is selected.

24. The controlling method for an A.I. based CBR event source tracking system of claim 19, wherein the second step further includes an offline mode of reading a prestored file and an online mode of loading pollution concentration data while being connected to a network in real time, in a process of receiving time zone-specific pollution concentration data calculated from a CBR pollution prediction tool.

25. The controlling method for an A.I. based CBR event source tracking system of claim 19, wherein the third step further includes a step of, in the process of tracking the pollution source by inversely calculating the time from current given pollution spread information currently given by using the pollution source tracking model, calculating a result of tracking the pollution source by using a GPU parallel high-speed calculation processing technique by returning a pollution spread situation several minutes or dozens of minutes before a current time by using a correlation analysis relationship of the time zone-specific pollution spread concentration calculated from the pollution spread prediction modeling tool by using the transformer technology which is the artificial intelligence technique.

26. The controlling method for an A.I. based CBR event source tracking system of claim 19, wherein the fourth step further includes a concrete output step of outputting a pollution source prediction result generated based on a time zone-specific pollution concentration calculated by the pollution source tracking modeling unit as output information including a pollution source tracking result image or video under the functional control of the control module unit.

27. The controlling method for an A.I. based CBR event source tracking system of claim 26, wherein the concrete output step further includes a sequential display step in which the pollution source tracking result image is sequentially shown according to a user definition or stored and displayed as a moving picture.

28. The controlling method for an A.I. based CBR event source tracking system of claim 19, wherein the fourth step further includes step S401 in which the pollution source tracking modeling unit receives, from the model input information acquisition unit, space information including pollution information in a pollution spread target region and a designation zone designated by the user under the functional control of the control module unit,
step 402 in which the pollution source tracking modeling unit receives, as input data, time-series pollution concentration image values in the pollution zone sequentially configured based on a modeling result learned by using the transformer technology based on the input information under the functional control of the control module unit, and calculates concentration values in the previous time zone through a pre-learned modeling computation during step 401,
step 403 of selecting a zone suspected as a first CBR occurrence region after a predetermined time zone by repeatedly performing step 402 during step 402, and
step 404 of reading various setting information acquired by an input information acquisition unit according to an analysis pattern, storing a calculation result in the memory, and storing the calculated result as an image or a moving picture for each time zone according to user setting, and displaying the image or video on a screen through an output unit under the functional control of the control module unit (screen display result) after step 403.

29. The controlling method for an A.I. based CBR event source tracking system of claim 28, wherein step 404 further includes a screen display step of displaying, on the screen, pollution concentration prediction values used as in which the screen display result is used as pre-input materials, and pollution concentration result values for each time reverse order predicted by using the transformer technology in an overlay format.

30. A controlling method for an A.I. based CBR event source tracking system, comprising:
a first step of acquiring, by an input information acquisition unit, model input information including at least any one information of modeling target space information, CBR pollution source information, and environmental setting information under functional control of a control module unit;
a second step of receiving pollution concentration data acquired by using a pollution spread prediction modeling tool in a zone under the functional control of the control module unit after the second step;
a third step of tracking, by a pollution source tracking modeling unit, a pollution source by inversely calculating a grid-specific pollution concentration in the zone by using transformer technology which is an artificial intelligence technique from the acquired space information and pollution spread data under the functional control of the control module unit after the second step; and
a fourth step of generating, by the control module unit, a pollution source tracking result generated based on the pollution concentration calculated by the pollution source tracking modeling unit, and displaying the generated output information to the outside after the third step.
